(19) United States
(12) Patent Application Publication
(10) Pub. No.: US 2011/0208452 A1
(43) Pub. Date: Aug. 25, 2011

(54) NON-INVASIVE METHOD OF DETERMINING THE ELECTRICAL IMPEDANCE OF A BATTERY

(75) Inventors: Rémy MINGANT, Vienne (FR); Valérie SAUVANT-MOYNOT, Lyon (FR); Julien BERNARD, Oullins (FR)

(73) Assignee: IFP Energies nouvelles

(21) Appl. No.: 13/021,014

(22) Filed: Feb. 4, 2011

(30) Foreign Application Priority Data
Feb. 25, 2010 (FR) 10/00778

(51) Int. Cl. G01R 31/36; G01N 27/416; G06F 19/00

(52) U.S. Cl. 702/63; 324/430

(57) ABSTRACT

A non-invasive method and device for determining the electrical impedance of an electrochemical system for electric power is disclosed. The voltage and current are measured at terminals as a function of time, and these measurements are converted to signals dependent on frequency. The signals dependent on frequency are subjected to at least one segmentation. For each segment, a power spectral density of the current signal Ψ_{I} dependent on frequency and the cross power spectral density of the voltage and current signals Ψ_{IV} dependent on frequency are determined for each segment. The electrical impedance of the electrochemical system is determined by calculating a ratio dependent on frequency of a mean of the power spectral densities Ψ_{I} dependent on frequency to a mean of the cross power spectral densities Ψ_{IV} dependent on frequency.

### BACKGROUND OF THE INVENTION

1. Field of the Invention

The present invention relates to a method and a device for determining the electrical impedance of a battery (lead, Ni—MH, Li-ion, etc.) at acquisition frequencies, notably during operation thereof in different types of devices or vehicles.

2. Description of the Prior Art

The electrochemical battery is one of the most critical components for vehicle applications, or solar power storage. Proper operation for these applications is based on a smart battery management system (BMS) whose purpose is to operate the battery with the best compromise between the various dynamic demand levels. This BMS measures several parameters such as voltage, current, temperature in order to determine the state of the battery.

The reactions that take place during charge and discharge of a battery are generally numerous and complex. When an electrochemical reaction is studied, a conventional characterization technique is electrical impedance spectrometry, which can allow modelling of the battery as a simple electrical system consisting of series or parallel capacitors and resistors.

The impedance of a system is accessible by measuring its electrical response when subjected to a sinusoidal signal. This signal can be a sinusoidal current or a sinusoidal voltage variation. An electrical component or a circuit supplied by a sinusoidal current Iₒ cos(ωt+φi) is used. If the voltage at terminals thereof is vₒ cos(ωt+φv), the impedance is defined as a complex number Z whose modulus is equal to ratio

$$\frac{{V}_{0}}{{I}_{0}}$$

and whose argument is equal to φ=φv−φi:

$$Z = \frac{{V}_{0}}{{I}_{0}} {e}^{j ϕ}$$

The total impedance of an element can also be represented by the complex sum of values Zᵣₑₑₗ and Z_{imag} such that [1]:

$$Z = {Z}_{r é el} + j \cdot {Z}_{imag} = \frac{{V}_{0}}{{I}_{0}} cos ϕ + j \cdot \frac{{V}_{0}}{{I}_{0 }} sin ϕ \qquad [ 1 ]$$

Impedance spectroscopy applies at the terminals of a battery a multi-frequency sinusoidal signal in order to know the impedance of the system at each frequency.

Conventionally, two types of representation are used to observe the impedance variations:

the Nyquist representation (diagram representing in abscissa the real parts and in ordinate the imaginary part),

the Bode representation (semilog-scale diagram representing generally both the modulus of Z (|Z|) and the phase, as a function of frequency).

Impedance spectra are also obtained using methods based on “signal processing” tools allowing switching from a time signal to a frequency signal, such as the Fourier series transform and the Laplace transform. The main methods are based on the application of superimposed sinusoidal signals and on the analysis of noises (notably white noise).

One of the methods allowing determination of the impedance of a system by means of harmonic analysis tools is the use of an incoming signal (U or I) consisting of a sum of sinusoids. This harmonic analysis signal has several distinct lines representative of the frequency of the sinusoids.

This method allows analysis of frequencies simultaneously, which saves considerable analysis time.

Noise analysis is also used to determine the impedance of a system. White noise for example is a set of random signals that can be described in the frequency domain by a constant power spectral density. Thus, at a given time, all the possible frequencies are superimposed, and not only some of them. This method thus is even faster than the previous one.

However, all these methods are based on the application of a particular signal to the electrochemical system for electric power storage whose electrical impedance is to be determined.

This therefore requires using sizeable means, such as a galvanostat, which makes it difficult to use in a vehicle in operation (lack of room, vehicle mass increase, etc.).

### SUMMARY OF THE INVENTION

The invention is a non-invasive method of determining the electrical impedance of an electrochemical system of battery type, which notably uses voltage and current measurements as a function of time, at the terminals of the battery under normal operating conditions, and of its elements, without superimposing additional signals.

The invention also is a device for implementing the method according to the invention, and systems, notably a smart battery management system, comprising such a device.

The method according to the invention is reliable and easy to implement in relation to prior art methods. It is applicable to nearly all the applications of batteries in operation.

The invention is a method of determining the electrical impedance of an electrochemical system for electric power storage which comprises:

acquiring signals measuring a voltage and a current as a function of time at terminals of the system and converting the time signals varying as a function of time into signals dependent on frequency;

carrying out segmentation of the signals dependent on frequency into segments;

determining for each segment, a power spectral density of a current signal Ψ_{I}(f) depending on frequency and a cross power spectral density of the voltage and current signals Ψ_{IV}(f) dependent on frequency for each of the segments f;

determining electrical impedance of the electrochemical system by calculating a ratio, dependent on frequency f, of a mean of the power spectral densities Ψ_{I}(f) to a mean of the cross power spectral densities Ψ_{IV}(f) dependent on frequency.

According to an embodiment, at least a second segmentation of the signals dependent on frequency, different from the first segmentation, is carried out so as to process the signals dependent on frequency at least twice.

The electrical impedance of the electrochemical system can be determined only for frequencies having power spectral densities above a set threshold, by applying a filter to the power spectral densities ΨI and ΨIV.

It is also possible to determine an indicator in order to evaluate an internal state of a battery or of one of the elements, from the electrical impedance.

According to an embodiment, the electrochemical system for electrical power storage is an element of a battery pack. In this case, the method according to the invention can be used in a method for identifying defective parts of a pack forming a battery, wherein an electrical impedance of each element of the pack is determined by the method according to the invention, and the electrical impedances of each of the elements are compared with one another. In this case also, the method according to the invention can be used in a method for driving a balancing system between elements of a pack forming a battery, wherein a complex electrical impedance of each element of the pack is determined by the method according to the invention.

Finally, according to the invention, the electrochemical system for electric power storage can be in operation.

The invention also relates to a device for determining complex electrical impedance of an electrochemical system for electric power storage. This device comprises:

a means for measuring voltage at terminals of the system as a function of time t;

means for measuring current at the terminals of the system as a function of time t;

using software to convert measurements of the voltage and the current as a function of time into signals dependent on frequency;

means for segmenting the signals dependent on frequency into at least one segment;

software executed on a processor for computing a power spectral density of current signal Ψ_{I}(f) and using a cross power spectral density of the voltage and current signals Ψ_{IV}(f) in each segment, wherein the spectral densities depend on frequency f; and

software executed on a processor, for computing electrical impedance of the electrochemical system from a ratio, depending on frequency f, of a mean of the power spectral densities Ψ_{I}(f) to a mean of the cross power spectral densities Ψ_{IV}(f).

The invention also relates to a system of estimating an internal state of an electrochemical system for electric power storage, comprising:

a device for determining complex electrical impedance of an electrochemical system for electric power storage;

a memory for storing a relation between a property relative to an internal state of the electrochemical system and a complex electrical impedance of the system; and

means, utilizing the relations, for computing a property relative to the internal state of the electrochemical system.

The invention also relates to a smart battery management system comprising a system for estimating an internal state of the battery according to the invention.

The invention also relates to a vehicle comprising a battery and a smart battery management system according to the invention.

The invention also relates to a photovoltaic system for electric power storage, comprising a system for estimating its internal state according to the invention.

### BRIEF DESCRIPTION OF THE DRAWINGS

Other features and advantages of the method and of the devices according to the invention will be clear from reading the description hereafter of embodiments given by way of non-limitative examples, with reference to the accompanying figures wherein:

FIG. 1 shows a current profile reproducing the demands on a battery of a hybrid vehicle in operation (integrating regenerative acceleration and braking phases), as well as the voltage response of the battery to this profile;

FIGS. 2A and 2B show impedance spectra of a hybrid vehicle battery module, obtained from a road signal without a DSP filter (FIG. 2A) and with DSP filter (FIG. 2B); and

FIG. 3 illustrates an impedance spectrum of a hybrid vehicle battery module, obtained from the method according to the invention, with successive segmentations.

### DETAILED DESCRIPTION OF THE INVENTION

The present invention relates to a non-invasive method of determining the complex electrical impedance of an electrochemical system of electric power storage, such as a battery.

A non-invasive method is a method allowing determination of the impedance without superimposing additional signals within the electrochemical system.

The method comprises using only the voltage U and current I measurements as a function of time. The method is particularly interesting for studying a battery while it is operating. These measurements are performed at the terminals of the battery and at the terminals of the elements making up the battery. This method comprises three stages.

1. Acquisition of Time Signals Measuring the Voltage and the Current

Current I is measured on a continuous basis as a function of time t in an electrified vehicle in operation. This signal is denoted by I(t). These measurements are performed at the terminals of the battery or at the terminals of the elements making up the battery. In fact, the current is the same at the battery terminals and at the element terminals if the elements are in series. On the other hand, if the elements are mounted in parallel, the current is not the same. The method according to the invention applies in both configurations. It can also be noted that the method according to the invention applies whatever the current levels. Voltage U is also measured on a continuous basis as a function of time t. This signal is denoted by U(t). These measurements are performed at the terminals of the battery or at the terminals of the elements making up the battery.

These measurements are performed conventionally, by detectors present in the batteries of this type used with an electrified vehicle.

The method is particularly interesting for studying a battery while it is operating. Operation also involves vehicle stop phases, at a red light for example, characterized by a zero current.

2. Conversion of Time Signals into Frequency Signals

In order to convert time signals U(t) and I(t) to frequency signals U(f) and I(f), the signal is processed by Fourier series transform. Vectors depending on frequency f are thus obtained.

3. Calculation of the Complex Electrical Impedance of the Electrochemical System

The complex electrical impedance of an electrochemical system, denoted by Z(f), is given by the relation U=ZI, thus Z=U/I.

Therefore, the relationship is:

$$Z ( f ) = \frac{U ( f )}{I ( f )}$$

In order to improve the impedance precision, the impedance is calculated using the power spectral densities.

The power spectral density (PSD) is a mathematical tool allowing representation of the various spectral components of a signal. It is equal to the square of the modulus of the Fourier transform of X(t), X(f) divided by half the acquisition time T:

$${Ψ}_{x} ( f ) = \frac{2}{T} {\vert X ( f ) \vert}^{2} \qquad [ 2 ]$$

There are also cross power spectral densities that consist of the conjugate of two Fourier transforms X(f) and Y(f):

$${Ψ}_{xy} ( f ) = \frac{2}{T} X ( f ) {Y}^{*} ( f ) \qquad [ 3 ]$$

Y*(f) is the conjugate of Y(f).

The complex electrical impedance of the electrochemical system can then be expressed by the following relation:

$$Z ( f ) = \frac{U ( f )}{I ( f )} = \frac{\frac{2}{T} U ( f ) {I}^{*} ( f )}{\frac{2}{T} I ( f ) {I}^{*} ( f )} = \frac{{Ψ}_{IU} ( f )}{{Ψ}_{I} ( f )} \\ with \text{:} \\ {Ψ}_{I } ( f ) = \frac{2}{T} {\vert I ( f ) \vert}^{2} \\ {Ψ}_{IU} ( f ) = \frac{2}{T} {I}^{*} ( f ) U ( f ) \qquad [ 4 ]$$

However, in practice, applying this formula does not provide sufficient precision to determine the impedance.

According to the invention, this problem is solved by segmenting the frequency signals U(f) and V) into N segments. Each one of these N signals is then dealt with independently.

The power spectral density Ψ_{I} and the cross power spectral density Ψ_{IV} are thus calculated on each of the N segments.

A mean of the power spectral densities Ψ_{I} and a mean of the cross power spectral densities Ψ_{IV} are then calculated.

Impedance Z(f) is calculated by calculating the ratio of these two means:

$$Z ( F ) = \frac{\frac{1}{N} {\sum }_{j = 1}^{N} \frac{2}{T} {U}_{j} ( f ) {I}_{j}^{*} ( f )}{\frac{1}{N} {\sum }_{j = 1}^{N} \frac{2}{T} {I}_{j} ( f ) {I}_{j}^{*} ( f )} = \frac{\frac{1}{N} {\sum }_{j = 1}^{N} {Ψ}_{UI} ( f )}{\frac{1}{N} {\sum }_{j = 1}^{N} {Ψ}_{I} ( f )}$$

This segmentation of the initial signals to N segments leads to a decrease in the frequencies studied, and of the low frequencies, due to the decrease in the number of data processed each time.

In fact, for a sample of p values measured at a constant time step, the frequency is a vector comprising numbers 1 to p, divided by the test duration. Thus, when the size of the sample is reduced, the number of frequencies studied and the number of low frequencies are also reduced. Furthermore, according to Nyquist-Shannon's theorem, “the sampling frequency of a signal must be equal to or greater than twice the maximum frequency contained in this signal, in order to convert this signal from an analog form to a digital form”. Thus, the higher frequencies must be removed (which reduces the number of frequencies studied).

According to the invention, this problem can be solved by means of a particular segmentation of the signals. In order to obtain an impedance with good precision over a large part of the frequency range, one solution uses processing the same signal several times, but with a different segmentation. Thus, values obtained from a mean worked out with a large amount of data are more precise and the low frequencies also have a relative precision. Several segmentations are thus carried out. Then, for each segmentation, each one of the N segments is processed independently. The power spectral density Ψ_{I} and the cross power spectral density Ψ_{IV} are thus calculated on each of the N′ segments. A new segmentation is then performed and power spectral densities are calculated again on each one of the N′ new segments. Finally, a mean of the power spectral densities Ψ_{I} and a mean of the cross power spectral densities Ψ_{IV} are calculated on each one of the N+N′+ . . . segments.

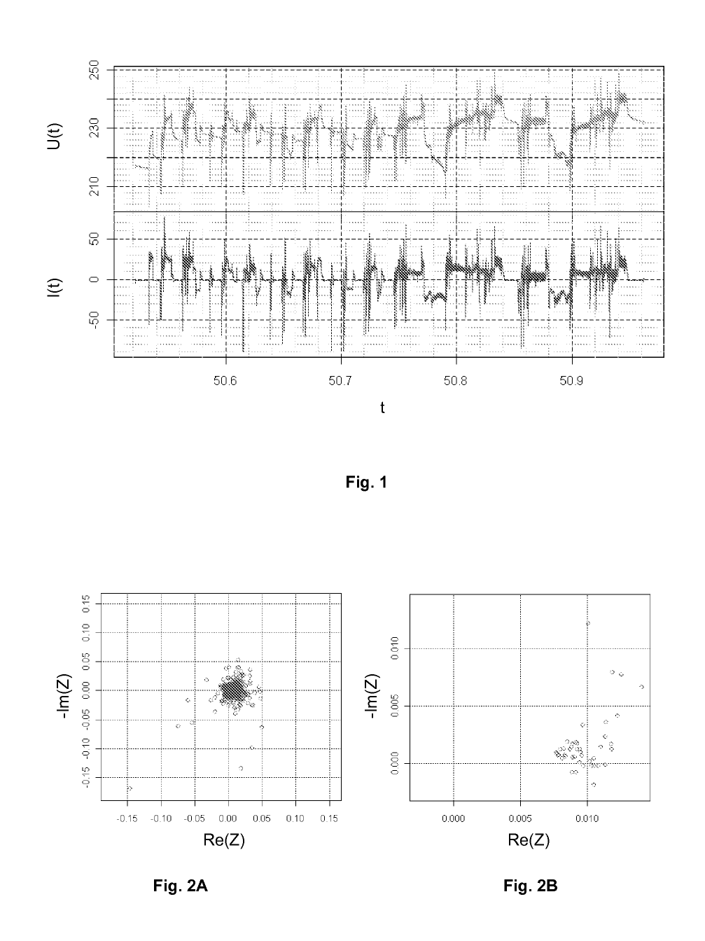

There is also a source of uncertainty concerning the processed signal. In fact, it is not white noise. Therefore, the power spectral density is not constant depending on the frequency, which involves U(f)/I(f) ratios that can be very uncertain (FIG. 2A).

According to the invention, this problem is solved by applying a filter system to the power spectral densities in order to select only the frequencies having the highest power spectral densities. It is possible to use, for example, a filter defining a threshold S, in determining the maximum sum of the power spectral density Ψ_{I} and of the cross power spectral density Ψ_{IV}, (Ψ_{I+}Ψ_{IV})^{max}=Ψ^{max}, and in selecting only the frequencies whose sum Ψ₁₊Ψ_{IV} is greater than Ψ^{max}/S.

Thus, the signal is more precise and the impedance obtained from calculation is coherent in relation to the impedances obtained from a common method.

Thus, the method of calculating the complex electrical impedance of the electrochemical system, from U(f) and I(f), comprises the following stages:

segmenting the signal at least once into N segments;

calculating the power spectral density Ψ_{I} and the cross power spectral density Ψ_{IV} for each segment; and

calculating the electrical impedance by calculating the ratio of the mean of the cross power spectral densities to the power spectral densities.

A power spectral density filter system can also be used to select only the frequencies having the highest power spectral densities.

### Example

In this example, a hybrid vehicle battery is cycled on a power bench according to a conventional road profile. Thus, the battery undergoes accelerations (battery discharging) and decelerations with regenerative braking (battery recharging).

A hybrid vehicle battery has a rated voltage of 202 V and a capacity of 6.5 Ah. It has 28 7.2-V, 6.5-Ah elements in series and each of its elements is a 6 1.2-V, 6.5-Ah Ni—MH element.

1. Acquisition of Time Signals Measuring the Voltage and the Current

On a power bench, this battery is recharged globally with a voltage measurement on each element. Thus, the available measurements are: 1 current intensity measurement and 28 voltage measurements of each element.

Determining the impedances is thus achieved on each element of the battery from a discharge current representing a road signal (FIG. 1).

2. Conversion of Time Signals to Frequency Signals

The signal is processed by a Fourier series transform, in order to convert the time signals to frequency signals.

3. Calculation of the Complex Electrical Impedance of the Electrochemical System

In order to obtain an impedance having good precision over a larger part of the frequency range, the same signal is processed several times, but with an increasingly low segmentation.

According to this example, the signals studied comprise 80,000 values. A first segmentation of N=5000 segments of 16 values is first carried out, then a second segmentation of 2500 segments of 32 values . . . 80,000/n segments of n values. The number n is an integer of 2^{k} type with k being a non-zero integer (because of the Cooley-Tukey algorithm commonly used for carrying out the Fourier transforms).

For each segmentation, the power spectral density Ψ_{I} and the cross power spectral density Ψ_{IV} are calculated on each segment.

The maximum Ψ^{max} of the power spectral density Ψ_{I} is determined and only the frequencies having power spectral densities above Ψ_{I}^{max}/10 are selected.

FIGS. 2A and 2B illustrate the impedance spectra of a hybrid vehicle battery module obtained from a road type signal without a DSP filter (FIG. 2A) and with a DSP filter (FIG. 2B). In FIG. 2B, the frequencies whose power spectral densities sum Ψ_{I+}Ψ_{IV} is above Ψ^{max}/10 are selected.

The electrical impedances of each element of the battery are then calculated by the formula as follows, and for the frequencies selected:

$$Z ( f ) = \frac{\frac{1}{N} {\sum }_{j = 1}^{N} {Ψ}_{UI} ( f )}{\frac{1}{N} {\sum }_{j = 1}^{N} {Ψ}_{I} ( f )}$$

Results

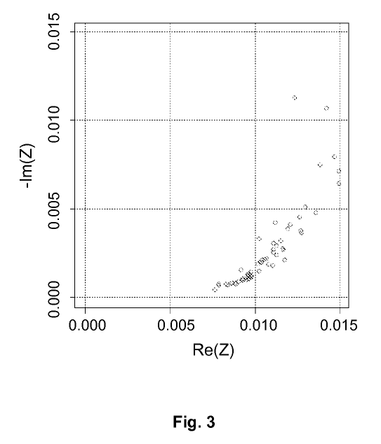

The impedances obtained by the method according to the invention are given in FIG. 3. Although the measurements are scattered, they are coherent in relation to the impedances obtained according to a conventional method (by superimposing a signal in sinusoids).

Use

The calculated complex electrical impedance of an electrochemical system for electric power storage, is a complex quantity. It can be represented in form of a Nyquist diagram −lm(Z)=F(ReZ) where each point corresponds to a frequency.

It is thus possible to distinguish the responses of fast phenomena (internal resistance to high frequencies), intermediate phenomena, such as reactions at the electrodes, and slow phenomena (ion diffusion in the medium at low frequencies, referred to as Warburg frequencies).

Thus calculating the impedance, an indicator for evaluating the internal state (state of health and state of charge) of a battery or of one of its elements is directly obtained.

In fact, the electrical impedance of an element is particularly sensitive to its internal state (state of health and state of charge). During operation, the state of charge varies rapidly but the state of health does not. Thus, determination of the impedance during operation reflects the state of health of a battery and of its elements.

Furthermore, the method according to the invention allows determination of the complex electrical impedance of each element of a pack making up a battery. The example described above shows the determination of the impedance simultaneously on the 28 elements (modules) of a battery.

Battery Pack Security

This information can then be used in order to identify the defective elements of the pack in a complete battery, and therefore to carry out the required maintenance operations. The failure of an element, characterized by an electrical contact degradation or loss, is readily spotted because its impedance spectrum differs from the spectra of the other elements of the pack.

Energy Management Improvement

This information can also be used in order to drive a balancing system between the elements of a pack.

The method according to the invention is applicable to all types of electrochemical systems, lead batteries, Ni—MH, Lithium-polymer and Li-ion, etc.

Devices

The invention also relates to a device for implementing the method according to the invention in order to determine the electrical impedance of an electrochemical system for electric power storage. This device comprises:

means for measuring the voltage U(t) at the terminals of the system as a function of time t, and when the system is in operation;

means for measuring the current I(t) at the terminals of the system as a function of time t, and when the system is in operation;

Fourier transform software for converting the measurements to frequency signals U(f) and I(f);

means for carrying out at least one segmentation of the frequency signals into several segments;

software for computing power spectral density of the current signal Ψ_{I} and the cross power spectral density of the voltage and current signals Ψ_{IV} in each segment; and

software for computing the electrical impedance of the electrochemical system for computing a ratio of a mean of the power spectral densities Ψ_{I} to a mean of the cross power spectral densities Ψ_{IV}.

The invention also relates to a system for estimating an internal state of an electrochemical system for electric power storage, comprising the complex electrical impedance determination device according to the invention. This system also comprises:

a memory for storing a relation between a property related to an internal state of the electrochemical system and complex electrical impedance of the system; and

means utilizing the relation for computing a property related to an internal state of the electrochemical system.

The invention also relates to a smart battery management system comprising a system for estimating an internal state of the battery according to the invention.

The invention also relates to a vehicle comprising a battery and a smart battery management system according to the invention.

Finally, the invention also relates to a photovoltaic system for electric power storage, comprising a system for estimating its internal state according to the invention.

1-13. (canceled)

14. A method for determining electrical impedance of an electrochemical system for electric power storage, comprising:
acquiring voltage and current signals which are a function of time at terminals of the system and converting the voltage and current signals into signals depending on frequency;
processing the signals depending on frequency into segments;
determining a power density of the current signal depending on frequency and a cross power spectral density of voltage and current signals depending on frequency; and
determining the electrical impedance of the electrochemical system by calculating a ratio depending on frequency of a mean of the power spectral density of the current signal to a mean of the cross power spectral density of the voltage and current signals depending on frequency.

15. A method as claimed in claim 14, wherein processing of at least a second segment is different from processing of a first segment.

16. A method as claimed in claim 14, wherein the electrical impedance of the electrochemical system is determined by filtering only the power spectral density of the voltage and current signals depending on frequency having power spectral densities above a set threshold.

17. A method as claimed in claim 15, wherein the electrical impedance of the electrochemical system is determined by filtering only the power spectral density of the voltage and current signals depending on frequency having power spectral densities above a set threshold.

18. A method as claimed in claim 14, comprising determining an indicator to evaluate an internal state of a battery or an element therein from the electrical impedance.

19. A method as claimed in claim 15, comprising determining an indicator to evaluate an internal state of a battery or an element therein from the electrical impedance.

20. A method as claimed in claim 16, comprising determining an indicator to evaluate an internal state of a battery or an element therein from the electrical impedance.

21. A method as claimed in claim 17, comprising determining an indicator to evaluate an internal state of a battery or an element therein from the electrical impedance.

22. A method as claimed in claim 14, wherein the electrochemical system for electric power storage comprises a battery pack.

23. A method as claimed in claim 15, wherein the electrochemical system for electric power storage comprises a battery pack.

24. A method as claimed in claim 16, wherein the electrochemical system for electric power storage comprises a battery pack.

25. A method as claimed in claim 17, wherein the electrochemical system for electric power storage comprises a battery pack.

26. A method as claimed in claim 18, wherein the electrochemical system for electric power storage comprises a battery pack.

27. A method as claimed in claim 19, wherein the electrochemical system for electric power storage comprises a battery pack.

28. A method as claimed in claim 20, wherein the electrochemical system for electric power storage comprises a battery pack.

29. A method as claimed in claim 21, wherein the electrochemical system for electric power storage comprises a battery pack.

30. A method as claimed in claim 21 comprising defective parts of a battery by determining an electrical impedance of each and comparing the electrical impedance of each part to the electrical impedance of other parts of the battery.

31. A method as claimed in claim 21 comprising balancing elements of the battery by comparing electrical impedance of each element to other elements.

32. A method as claimed in claim 14, comprising determining the electrical impedance of the system during operation thereof.

33. A method as claimed in claim 15, comprising determining the electrical impedance of the system during operation thereof.

34. A method as claimed in claim 16, comprising determining the electrical impedance of the system during operation thereof.

35. A method as claimed in claim 18, comprising determining the electrical impedance of the system during operation thereof.

36. A method as claimed in claim 22, comprising determining the electrical impedance of the system during operation thereof.

37. A method as claimed in claim 30, comprising determining the electrical impedance of the system during operation thereof.

38. A device for determining complex electrical impedance of an electrochemical system providing electric power storage, comprising:
means for measuring voltage at terminals of the system as a function of time;
means for measuring current at the terminals of the system as a function of time;
software, executed on a processor, which converts measurements of the voltage and current into signals depending on frequency;
means for converting the signals depending on frequency into segments;
software, executed on a processor, which for each segment computes a power spectral density of the measured current depending on frequency and a cross power spectral density of a voltage and current signals depending on frequency; and
software, executed on a processor, which computes the electrical impedance of the electrochemical system by computing a ratio of a mean of the power spectral density of the current signal to a mean of the cross power spectral densities of the voltage and current signals depending on frequency.

39. A system of estimating an internal state of an electrochemical system for electric power storage including a device for determining complex electrical impedance of an electrochemical system providing electrical power storage comprising:
means for measuring voltage at terminals of the system as a function of time;
means for measuring current at the terminals of the system as a function of time;
software, executed on a processor, which converts measurements of the voltage and current into signals depending on frequency;
means for converting the signals depending on frequency into segments;
software, executed on a processor, which computes for each segment a power spectral density of the measured current depending on frequency and a cross power spectral density of a voltage and current signals depending on frequency; and
software, executed on a processor, which computes the electrical impedance of the electrochemical system by computing a ratio of a mean of the power spectral density of the current signal to a mean of the cross power spectral densities of the voltage and current signals depending on frequency;
a memory for storing a relation between a property related to an internal state of the electrochemical system and electrical impedance of the system; and
means, utilizing the relation, for computing the property related to the internal state of the electrochemical system.

40. A smart battery management system comprising a system for estimating an internal state including a device for determining complex electrical impedance of an electrochemical system providing electrical power storage comprising:
means for measuring voltage at terminals of the system as a function of time;
means for measuring current at the terminals of the system as a function of time;
software, executed on a processor, which converts measurements of the voltage and current into signals depending on frequency;
means for converting the signals depending on frequency into segments;
software, executed on a processor, which computes for each segment a power spectral density of the measured current depending on frequency and a cross power spectral density of a voltage and current signals depending on frequency; and
software, executed on a processor, which computes the electrical impedance of the electrochemical system by computing a ratio of a mean of the power spectral density of the current signal to a mean of the cross power spectral densities of the voltage and current signals depending on frequency;
a memory for storing a relation between a property related to an internal state of the electrochemical system and electrical impedance of the system; and
means, utilizing the relation, for computing the property related to the internal state of the electrochemical system.

41. A vehicle comprising a battery and a smart battery management system including a system for estimating an internal state including a device for determining complex electrical impedance of an electrochemical system providing electrical power storage comprising:
means for measuring voltage at terminals of the system as a function of time;
means for measuring current at the terminals of the system as a function of time;
software, executed on a processor, which converts measurements of the voltage and current into signals depending on frequency;
means for converting the signals depending on frequency into segments;
software, executed on a processor, which computes for each segment a power spectral density of the measured current depending on frequency and a cross power spectral density of a voltage and current signals depending on frequency; and
software, executed on a processor, which computes the electrical impedance of the electrochemical system by computing a ratio of a mean of the power spectral density of the current signal to a mean of the cross power spectral densities of the voltage and current signals depending on frequency;
a memory for storing a relation between a property related to an internal state of the electrochemical system and electrical impedance of the system; and
means, utilizing the relation, for computing the property related to the internal state of the electrochemical system.

42. A photovoltaic system for electric power storage including a system for estimating an internal state of an electrochemical system including a device for determining complex electrical impedance of an electrochemical system providing electrical power storage comprising:
means for measuring voltage at terminals of the system as a function of time;
means for measuring current at the terminals of the system as a function of time;
software, executed on a processor, which converts measurements of the voltage and current into signals depending on frequency;
means for converting the signals depending on frequency into segments;
software, executed on a processor, which computes for each segment a power spectral density of the measured current depending on frequency and a cross power spectral density of a voltage and current signals depending on frequency; and
software, executed on a processor, which computes the electrical impedance of the electrochemical system by computing a ratio of a mean of the power spectral density of the current signal to a mean of the cross power spectral densities of the voltage and current signals depending on frequency;
a memory for storing a relation between a property related to an internal state of the electrochemical system and electrical impedance of the system; and
means, utilizing the relation, for computing the property related to the internal state of the electrochemical system.
